(19) United States
(12) Patent Application Publication
(10) Pub. No.: US 2020/0235741 A1
(43) Pub. Date: Jul. 23, 2020

(54) VOLTAGE LEVEL SHIFTER WITH ADJUSTABLE THRESHOLD VOLTAGE VALUE FOR INTEGRATED CIRCUIT

(71) Applicant: Aplus Microstructure Electronics Co., Ltd., Changzhou (CN)

(72) Inventor: SUI-HO TSAI, Changzhou (CN)

(21) Appl. No.: 16/254,638

(22) Filed: Jan. 23, 2019

(51) Int. Cl. H03K 19/0185

(52) U.S. Cl. CPC H03K 19/018521

(57) ABSTRACT

Disclosed is a voltage level shifter with threshold voltage value for integrated circuits. The voltage level shifter is composed of two first transistors, two second transistors and a bias control circuit. The bias control circuit is electrically connected to substrates of the two first transistors simultaneously, and provides a bias voltage to substrates of the two first transistors, the drain of each of the first transistor is electrically connected to the gate of one of the second transistors and the drain of the other of the second transistors simultaneously. Sources and substrates of the two second transistors are electrically connected to one of a low-potential input voltage and a high-potential input voltage, and sources of the two first transistors are electrically connected to the other of the low-potential input voltage and the high-potential input voltage.

### TECHNICAL FIELD

The present invention relates to a voltage level shifter for an integrated circuit, in particular to a voltage level shifter equipped with a bias controller, so that the voltage level shifter of the present invention is capable of adjusting threshold voltage values of transistors through the bias voltage controller and further indirectly adjusting an operating range of a low voltage of an input voltage signal or of a high voltage of an input voltage signal.

### BACKGROUND OF THE INVENTION

With the rapid development of technology, thin-film transistor liquid crystal displays (TFT LCD) have been widely applied in electronic products such as personal computer monitors, televisions, mobile phones and digital cameras. Thin-film transistors are controlled by means of frequency signals to send display data sequentially to pixels of the LCD panel. Since the frequency signals require a higher voltage level, they must firstly be subjected to voltage level shifting by a voltage level shifter, and then high-voltage frequency signals subjected to the voltage level shifting are supplied to the thin film transistors, and thanks to the booming of the semiconductor technology, the voltage level shifter is implemented in the form of an integrated circuit.

With reference to FIG. 1, an existing voltage level shifter 1 for a thin-film transistor liquid crystal display is disclosed. As shown, the existing voltage level shifter 1 has a first voltage level shifting unit 10 and a second voltage level shifting unit 11, where the first voltage level shifting unit 10 has two first PMOS transistors 101 and two first NMOS transistors 102; and the second voltage level shifting unit 11 has two second PMOS transistors 111 and two second NMOS transistors 112.

As shown, the source of each of the first PMOS transistors 101 is electrically connected to an operating voltage (VDD), and the source and the substrate of each of the first PMOS transistors 101 are electrically connected to each other, then the drain of each of the first PMOS transistors 101 is electrically connected to the drain of one of the first NMOS transistors 102 and the gate of the other of the first NMOS transistors 102 simultaneously respectively to form a first connecting point 12 and a second connecting point 13, and the source and the substrate of each of the first NMOS transistors 102 are electrically connected to each other, where the source of each of the first NMOS transistors 102 is electrically connected to a reverse charge pump voltage (VGL).

In addition, the source and the substrate of each of the second POMS transistors are electrically connected to each other, and the source of each of the second POMS transistors is electrically connected to a boosted charge pump voltage (VGH), where the source and the substrate of each of the second NMOS transistors 112 are electrically connected to each other, and the source of each of the second NMOS transistors 112 is electrically connected to the reverse charge pump voltage (VGL), then the drain of each of the second NMOS transistors 112 is electrically connected to the drain of one of the second PMOS transistors 111 and the gate of the other of the second PMOS transistors 111 simultaneously, and the gate of one of the second NMOS transistors 112 is electrically connected to the first connecting point 12, and the gate of the other of the second NMOS transistors 112 is electrically connected to the second connecting point 13.

In a specific application, in order to supply the high-voltage frequency signals subjected to the voltage level shifting to the thin-film transistors, the transistors used in the existing voltage level shifter 1 must be able to withstand a high voltage (greater than 30 V), and further threshold voltage values of the transistors used in the existing voltage level shifter 1 are greater than those of common transistors. Moreover, the two first PMOS transistors 101 must be specially designed to reduce the threshold voltage value (Vth) of the first PMOS transistors 101, whereby when the gate of each two first PMOS transistors 101 receives an input voltage signal with a voltage level between GND and VDD, the first voltage level shifting unit 10 reduces the voltage level of the input voltage signal, and further reduces the low voltage value of the voltage level, so that the low voltage value of the voltage level of the input voltage signal is shifted from GND to VGL, and further that the voltage level of the input voltage signal is shifted from GND-VDD to VGL-VDD.

Then, when the input voltage signal with the voltage level between VGL and VDD is transmitted to the two second NMOS transistors 112 of the second voltage level shifting unit 11 via the first connecting point 12 and the second connecting point 13, the second voltage level shifting unit 11 increases the voltage level of the input voltage signal, so that the high voltage value of the voltage level is converted from VDD to VGH, and further that the voltage level is converted from VGL-VDD to VGL-VGH, where GND represents a voltage reference point, VDD represents the operating voltage, VGL represents the reverse charge pump voltage, and VGH represents the boosted charge pump voltage.

It can be seen from the foregoing description that when the existing voltage level shifter 1 reduces or increases the voltage level of the input voltage signal, it is necessary for the existing voltage level shifter 1 to use two specially designed first PMOS transistors 101 to reduce or increase the voltage level of the input voltage signal, which may result in increasing the material cost of the existing voltage level shifter 1 due to the adoption of the two specially designed first PMOS transistors 101.

### SUMMARY OF THE INVENTION

A main objective of the present invention is to adjust threshold voltage values of transistors by using a bias voltage circuit and common transistors instead of using specially designed transistors, and further adjust the high voltage value and the low voltage value of the operating voltage, and the material cost is lowered due to no adoption of the specially designed transistors.

To achieve the foregoing objective, the present invention relates to a voltage level shifter with the adjustable threshold voltage value in an integrated circuit, which is composed of two first transistors, two second transistors and a bias control circuit. The two first transistors have a threshold voltage value indicating a voltage level, the gate of each of two first transistors is configured to receive an input voltage signal, and the voltage level of the input voltage signal is between a low voltage value and a high voltage value; and drains of the first transistors are electrically connected to the gate of one of the second transistors and the drain of the other of the second transistors simultaneously to form an output contact.

Sources and substrates of the two second transistors are electrically connected to one of a low-potential input voltage and a high-potential input voltage, and sources of the two first transistors are electrically connected to the other of the low-potential input voltage and the high-potential input voltage, where the bias control circuit is electrically connected to substrates of the two first transistors simultaneously, and provides a bias voltage to the substrate of the two first transistors to reduce the threshold voltage value of the first transistors to adjust one of the low voltage value and the high voltage value and further convert the input voltage signal into an output voltage signal transmitted to the output contact; and the low voltage value or the high voltage value of the voltage level of the output voltage signal is different from that of the input voltage signal.

In a preferred embodiment, the first transistors are set as PMOS transistors, and the second transistors are set as NMOS transistors, so that the high voltage value of the input voltage signal can be reduced via the bias voltage.

In another preferred embodiment, the first transistors are set as NMOS transistors, and the second transistors are set as PMOS transistors, so that the low voltage value of the input voltage signal can be increased via the bias voltage.

In the foregoing two embodiments, the high-potential voltage is set as an operating voltage (VDD) or a boosted charge pump voltage (VGH), and the low-potential voltage is set as a reverse charge pump voltage (VGL), where the voltage value of the reverse charge pump voltage (VGL) is between −15 V and −5 V, and the voltage value of the boosted charge pump voltage (VGH) is between 10 V and 50 V. In addition, the bias control circuit generates a bias voltage by means of one of superposition of a diode superposition method, a bandgap reference voltage circuit or superposition of diodes and resistors.

The voltage level shifter is characterized by being composed of the bias control circuit, the two first transistors and the two second transistors, where the bias control circuit reduces the threshold voltage value of the first transistors, and the low voltage value or the high voltage value of the input voltage signal is adjusted. Therefore, with the four transistors and the bias control circuit in the present invention, the bias control circuit reduces the threshold voltage values of the transistors, and further adjusts the high and low voltage values of the output and input voltage signals, such that the material cost may be lowered by eliminating the use of specially designed transistors.

### BRIEF DESCRIPTION OF THE DRAWINGS

FIG. 1 is a schematic diagram of an existing voltage level shifter in an integrated circuit;

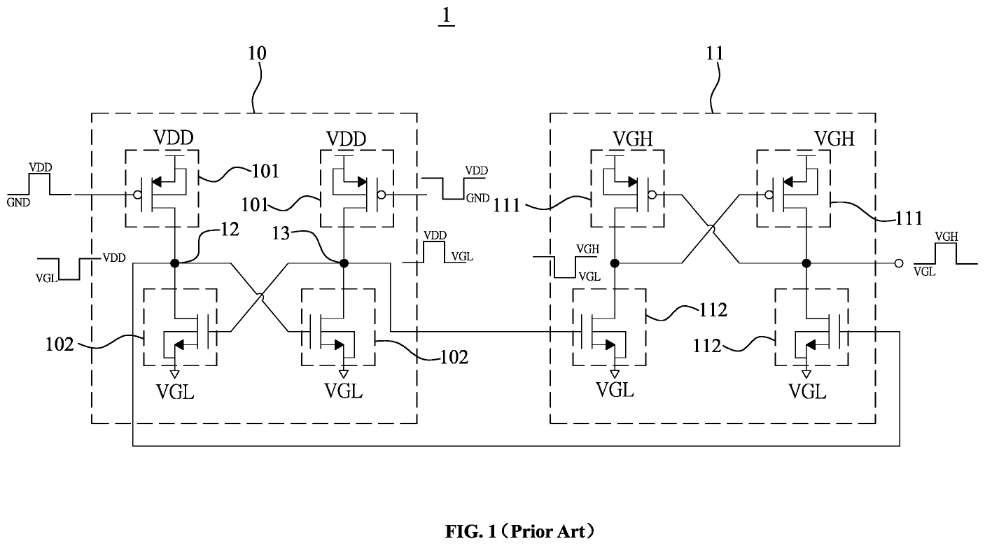

FIG. 2 is a schematic diagram of a voltage level shifter for adjusting a threshold voltage value in an integrated circuit according to a first preferred embodiment of the present invention;

FIG. 3 is a schematic diagram of a specific application of a voltage level shifter for adjusting a threshold voltage value in an integrated circuit according to a first preferred embodiment of the present invention;

FIG. 4 is a schematic diagram of a voltage level shifter for adjusting a threshold voltage value in an integrated circuit according to a second preferred embodiment of the present invention;

FIG. 5 is a schematic diagram of a specific application of a voltage level shifter for adjusting a threshold voltage value in an integrated circuit according to a second preferred embodiment of the present invention; and

FIG. 6 is a schematic diagram of a voltage level shifter for adjusting a threshold voltage value in an integrated circuit according to a third preferred embodiment of the present invention.

### REFERENCE NUMERALS

1—existing voltage level shifter
10—first voltage level shifting unit
101—first PMOS transistor
102—first NMOS transistor
11—second voltage level shifting unit
111—second PMOS transistor
112—second NMOS transistor
12—first connecting point
13—second connecting point
2—voltage level shifter with adjustable threshold voltage value for integrated circuit
20—first transistor
21—second transistor
22—bias control circuit
23—output contact
3—boost voltage level shifter
4—buck voltage level shifter

### DETAILED DESCRIPTION OF EMBODIMENTS

In order to facilitate further understanding of the structure, use and the features of the present invention, preferred embodiments will be described below in detail with reference to accompanying drawings as follows.

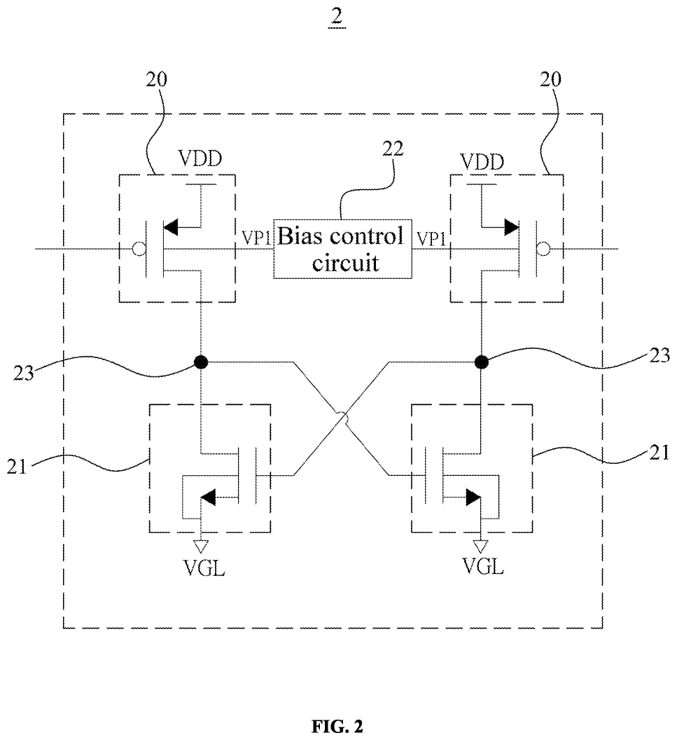

With reference to FIG. 2, in a first preferred embodiment, the present invention relates to a voltage level shifter 2 capable of adjusting a threshold voltage value in an integrated circuit. The voltage level shifter 2 is composed of two first transistors 20, two second transistor 21 and a bias voltage circuit 22. The two first transistors 20 and the two second transistors 21 each have a source, a drain, a substrate and a gate, and both of the two first transistors 20 have a threshold voltage value indicating a voltage level. The two first transistors 20 are PMOS transistors, and the two second transistors 21 are NMOS transistors.

As shown in FIG. 2, the source of each of the first transistors 20 is electrically connected to an operating voltage (VDD) as a high-potential input voltage, and the substrate of each of the first transistors 20 is electrically connected to the bias voltage circuit 22. The drain of one of the second transistors 21 and the gate of the other of the second transistors 21 are electrically connected to the drain of the same first transistor 20 simultaneously to form an output contact 23. The source of each of the second transistors 21 is electrically connected to a reverse charge pump voltage (VGL) as a low-potential input voltage, and the voltage value of the reverse charge pump voltage (VGL) is smaller than that of the operating voltage (VDD). In addition, the substrate and the source of each of the second transistors 21 are electrically connected to each other. In this embodiment, the voltage value of the reverse charge pump voltage (VGL) is in the range of −15 to −5 V to form the low-potential input voltage.

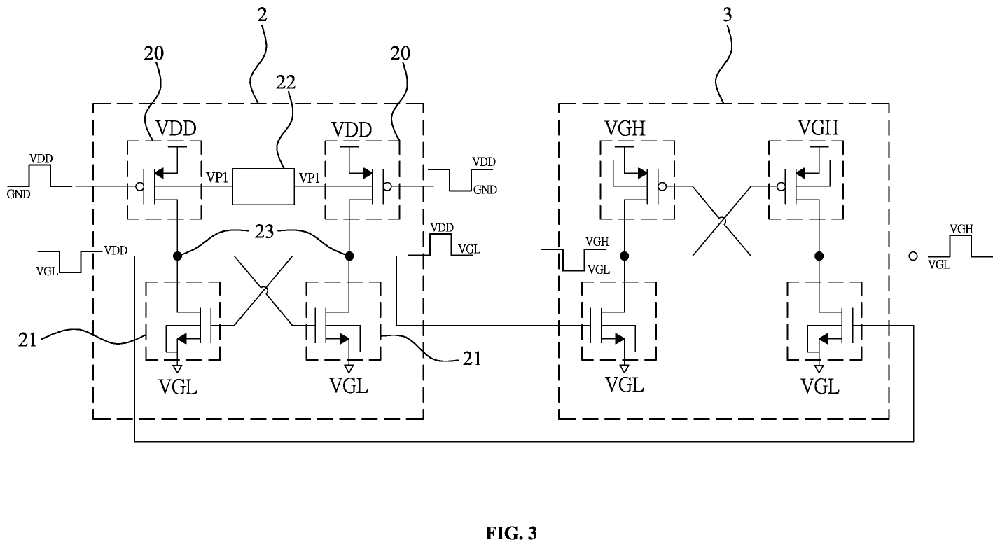

Referring to FIG. 3, in a specific application, the voltage level shifter 2 with adjustable threshold voltage value in an integrated circuit is used to reduce a threshold voltage value of an input voltage signal. The output contact 23 is electrically connected to a boost voltage level shifter 3 for increasing a voltage value of the input voltage signal. As shown, gates of two first transistors 20 receive the input voltage signals, and a voltage level of the input voltage signal is between a low voltage value and a high voltage value. The low voltage value of the input voltage signal as shown is set to be higher than the low-potential input voltage GND, and a high voltage value of the input voltage signal is set to be equal to the high-potential input voltage VDD. Further, the bias voltage circuit 22 generates a bias voltage (VP1), and transmits the bias voltage (VP1) to the substrate of each of the first transistors 20. In this embodiment, the bias voltage (VP1) decreases a threshold voltage value of the first transistors 20, thereby reducing the high voltage value VDD of the input voltage signal. The low voltage value GND of the input voltage signal is reduced by the connecting method between the two first transistors 20 and the two second transistors 21. Therefore, the input voltage signal decreases the threshold voltage value of the first transistors 20 by means of the bias voltage (VP1), and reduces the high voltage value of the input voltage signal and the low voltage value of the input voltage signal by means of the connecting method between the two first transistors 20 and the two second transistors 21, thereby converting a voltage level of the input voltage signal to be shifted from GND-VDD to VGL-VDD to form an output voltage signal, allowing the output voltage signal to be transmitted to an output contact 23. The GND is a voltage reference point (e.g., ground), and the voltage value of the bias voltage (VP1) is less than the operating voltage (VDD). In this embodiment, the bias control circuit generates a bias voltage by means of one of superposition of a diode superposition method, a bandgap reference voltage circuit or superposition of diodes and resistors.

In addition, the threshold voltage value of the first transistors 20 is reduced by the bias voltage (VP1) through a body effect, wherein the body effect may be expressed as:

|Vₜₕ|=|Vₜₕ₀|+γ(\sqrt{2|ø_{f}|−V_{sb}}−\sqrt{2|ø_{f}|})

where |Vₜₕ₀| represents |Vₜₕ| when V_{sb}=0V, γ represents a bulk effect coefficient, and ø_{f} is a Fermi potential. Therefore, the threshold voltage |Vₜₕ| decreases as V_{sb} increases.

Then, when the output voltage signal is transmitted to the boost voltage level shifter 3 via the output contact 23, the output voltage signal boosts the high voltage value VDD of the input voltage signal by the boost voltage level shifter 3, such that the high voltage value of the output voltage signal is changed from VDD to VGH, and further the voltage level of the output voltage signal is changed from VGL-VDD to VGL-VGH.

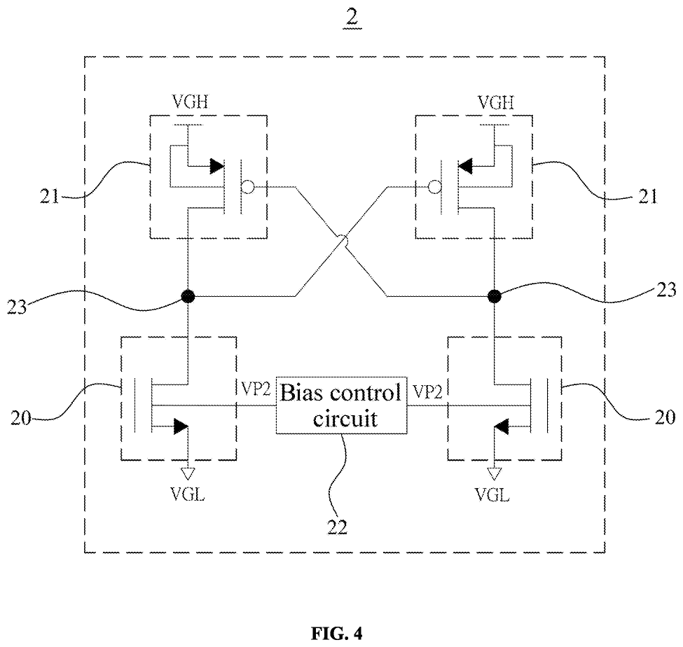

With reference to FIG. 4, the second preferred embodiment differs from the first preferred embodiment in it's first transistors 20 and second transistors 21. While the bias voltage circuit 22 is the same as the first preferred embodiment, and description regarding same will be omitted in this embodiment.

In this embodiment, both the two first transistors 20 are NMOS transistors, and both the two second transistors 21 are PMOS transistors. As shown in FIG. 4, the source of each of the first transistors 20 is electrically connected to a reverse charge pump voltage (VGL) as a low-potential input voltage, and the source of each of the second transistors 21 is electrically connected to a boost charge pump voltage (VGH) as a high-potential input voltage.

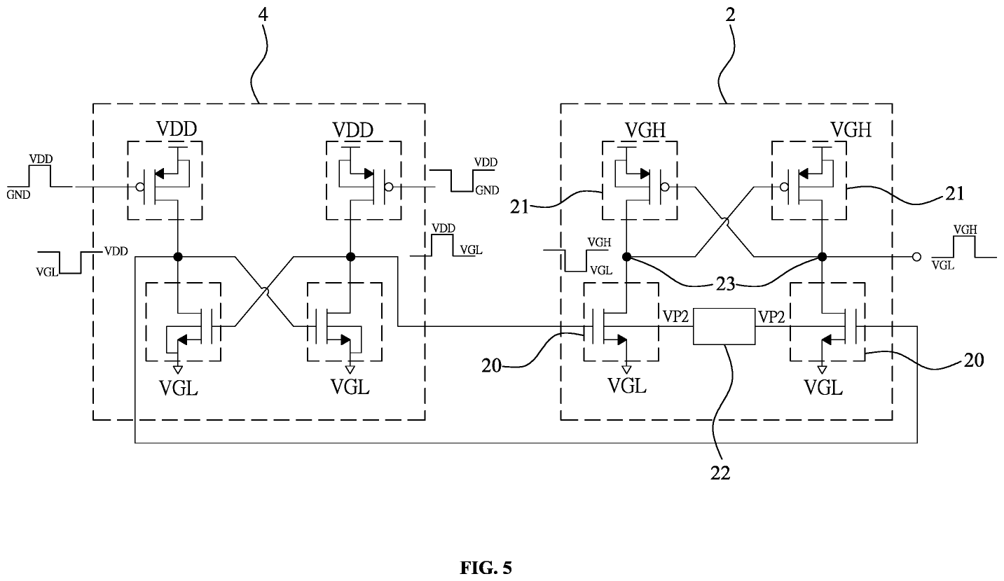

With reference to FIG. 5, in a specific application, the voltage level shifter 2 with adjustable threshold voltage value in an integrated circuit is used for increasing a voltage value of an input voltage signal and used in combination with a buck voltage level shifter 4, and the buck voltage level shifter 4 is used for reducing the voltage value of the input voltage signal. As shown in FIG. 5, the buck voltage level shifter 4 receives the input voltage signal, and the voltage level of the input voltage signal is between a low voltage value and a high voltage value as in the first preferred embodiment. As shown in FIG. 5, the low voltage value of the input voltage signal is set to be greater than the low-potential input voltage GND, and the high voltage value of the input voltage signal is set to be equal to the high-potential input voltage VDD, then the buck voltage level shifter 4 shifts an input voltage signal with the voltage level between GND and VDD to an input voltage signal with a voltage level between VGL and VDD.

Then, the buck voltage level shifter 4 transmits the input voltage signal with the voltage level between VGL and VDD to the gate of each of the first transistors 20 of the voltage level shifter 2, and a bias control circuit 22 generates a bias voltage (VP2) and transmits the bias voltage (VP2) to the substrate of each of the first transistors 20. In this embodiment, the bias voltage (VP2) decreases a threshold voltage value of the first transistors 20, further increases the low voltage value of the input voltage signal, and increases the high voltage value VDD of the input voltage signal through by means of connecting between the two first transistors 20 and the two second transistors 21. The voltage level of the input voltage signal is converted from VGL-VDD to VGL-VGH to form an output voltage signal to be transmitted to an output contact 23, such that the high and low voltage values of the output voltage signal are different from those of the input voltage signal. Therefore, the voltage level shifter 2 with adjustable threshold value in the integrated circuit of the present invention adjusts a threshold value of the input voltage signal only by using four transistors in combination with the bias voltage circuit 22. A voltage value of a reverse charge pump voltage (VGL) in this embodiment is between −15 V and −5 V to form a low voltage, and a voltage value of a boosted charge pump voltage (VGH) is between 10 V and 50 V to form a high voltage. The voltage value of the bias voltage (VP2) is greater than that of the reverse charge pump voltage (VGL).

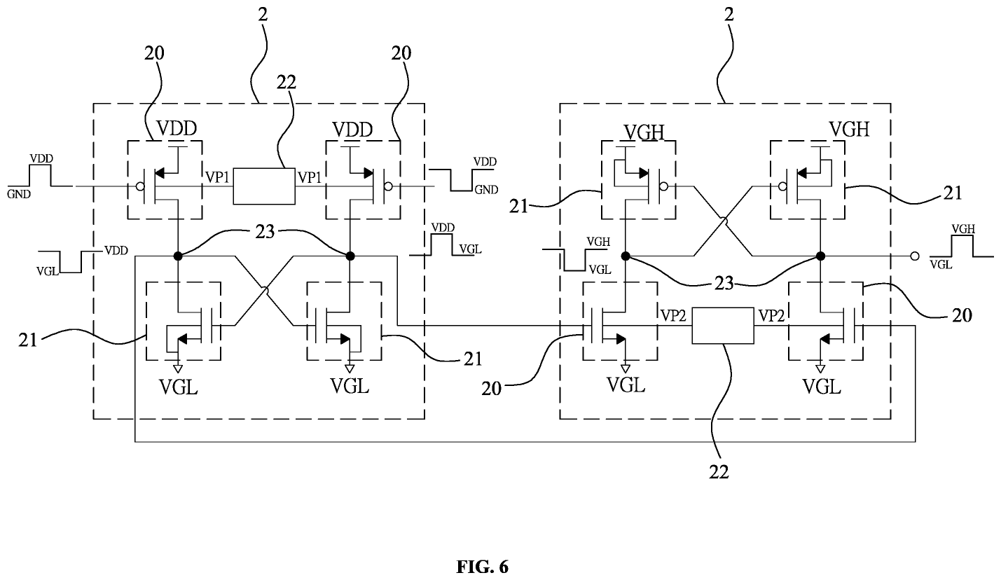

Referring to FIG. 6, a third preferred embodiment differs from the first preferred embodiment in that a voltage level shifter 2 with adjustable threshold voltage value in an integrated circuit is connected to another voltage level shifter 2 with adjustable threshold voltage value in an integrated circuit as in the second preferred embodiment. One of the voltage level shifters 2 with adjustable threshold voltage value in the integrated circuit converts a voltage level of the input voltage signal from GND-VDD to VGL-VDD, such that the input voltage signal is converted into an output voltage signal transmitted to an output contact 23. While the other voltage level shifter 2 with adjustable threshold voltage value in the integrated circuit converts a voltage level of the output voltage signal from VGL-VDD to VGL-VGH.

The above exemplified embodiments are intended to be merely illustrative of the present invention, and are not to be construed as limiting the present invention. Various simple variations and modifications made by those skilled in the art according to the scope and description of the present invention should fall within the scope of the present invention without departing from the spirit and scope of the present invention.

What is claimed is:

1. A voltage level shifter with adjustable threshold voltage value in an integrated circuit, comprising:
two first transistors;
two second transistors; and
a bias control circuit;
wherein the two first transistors have a threshold voltage value indicating a voltage level; gates of the two first transistors are configured to receive input voltage signals, and a voltage level of the input voltage signal is between a low voltage value and a high voltage value; a drain of each of the first transistor is electrically connected to the gate of one of the second transistors and a drain of the other of the second transistors simultaneously to form an output contact;
the source and substrate of each of the two second transistors are electrically connected to one of a low-potential input voltage and a high-potential input voltage; and sources of the two first transistors are electrically connected to the other of the low-potential input voltage and the high-potential input voltage; wherein the bias control circuit is electrically connected to substrates of the two first transistors simultaneously, and provides a bias voltage to substrates of the two first transistors such that a threshold voltage value of the first transistors is decreased to adjust one of the low voltage value or the high voltage value and further converts the input voltage signal into an output voltage signal transmitted to the output contact; and the low voltage value of the voltage level of the output voltage signal is different from that of the input voltage signal, or the high voltage value of the voltage level of the output voltage signal is different from that of the input voltage signal.

2. The voltage level shifter of claim 1, wherein the first transistors are PMOS transistors, and the second transistors are NMOS transistors, such that the high voltage value of the input voltage signal is reduced through the bias voltage.

3. The voltage level shifter of claim 1, wherein the first transistors are NMOS transistors, and the second transistors are PMOS transistors, such that the low voltage value of the input voltage signal is increased through the bias voltage.

4. The voltage level shifter of claim 1, wherein the high-potential voltage is set as an operating voltage (VDD) or a boosted charge pump voltage (VGH), and the low-potential voltage is set as a reverse charge pump voltage (VGL).

5. The voltage level shifter of claim 4, wherein the voltage value of the reverse charge pump voltage (VGL) is between −15 V and −5 V, and the voltage value of the boosted charge pump voltage (VGH) is between 10 V and 50 V.

6. The voltage level shifter of claim 1, wherein the bias control circuit generates a bias voltage by means of one of superposition of a diode superposition method, a bandgap reference voltage circuit or superposition of diodes and resistors.
